(19) United States
(12) Patent Application Publication
(10) Pub. No.: US 2018/0053791 A1
(43) Pub. Date: Feb. 22, 2018

(54) ARRAY SUBSTRATE AND DISPLAY DEVICE WITH THE ARRAY SUBSTRATE

(71) Applicant: InnoLux Corporation, Miao-Li County (TW)

(72) Inventors: Li-Wei SUNG, Miao-Li County (TW); Fu-Yuan HSIAO, Miao-Li County (TW); Chung-Le CHEN, Miao-Li County (TW); Hung-Hsun CHEN, Miao-Li County (TW)

(21) Appl. No.: 15/641,653

(22) Filed: Jul. 5, 2017

Related U.S. Application Data
(60) Provisional application No. 62/376,930, filed on Aug. 19, 2016.

(30) Foreign Application Priority Data
Apr. 27, 2017 (CN) 201710287482.7

(51) Int. Cl. H01L 27/12; H01L 27/32; G02F 1/1368; G02F 1/1343; G02F 1/1339; G02F 1/1362

(52) U.S. Cl. CPC H01L 27/1222; H01L 27/3262; G02F 1/1368; G02F 2202/10; G02F 1/13394; G02F 1/136209; G02F 1/134309

(57) ABSTRACT

An array substrate includes a substrate, a first transistor and an optical modulating layer. The first transistor is disposed on the substrate and includes a first semiconductor layer having a first channel region. A first gate is disposed on the first semiconductor layer. First source and first drain are electrically connected to the first semiconductor layer respectively. A first interval is located between the first source and the first drain and the first channel region corresponds to the first interval. A first insulating layer is disposed between the first semiconductor layer and the first gate. A second insulating layer covers the first source, the first drain and the first channel region. The optical modulating layer is disposed on the second insulating layer and has an optical density (OD) in greater than or equal to 0.1 and less than or equal to 6.

### CROSS REFERENCE TO RELATED APPLICATIONS

This application claims the benefit of U.S. Provisional Application No. 62/376,930, filed on Aug. 19, 2016 and claims priority of Chinese Patent Application No. 201710287482.7, filed on Apr. 27, 2017, the entirety of which is incorporated by reference herein.

### BACKGROUND

### Field of the Disclosure

The disclosure relates to a display technology, and in particular to an array substrate having an optical modulating structure and a display device including the array substrate.

### Description of the Related Art

In recent years, display devices have been widely used in electronic devices. In the array substrate of such a display device, a thin film transistor (TFT) is typically used as a switching element to control each pixel region, or to serve as a driving element in a driving circuit. Recently, a TFT using a metal oxide semiconductor layer as an active layer (or a channel layer) has been receiving attention due to its properties of high mobility and good transparency.

The property (e.g., threshold voltage) of the TFT, however, is easily impacted when external light irradiates the metal oxide (e.g., indium gallium zinc oxide, IGZO) layer. As a result, the quality of the display device suffers.

Thus, there exists a need in the art for development of a novel array substrate capable of mitigating or eliminating the aforementioned problems.

### SUMMARY

An exemplary embodiment of an array substrate is provided. The array substrate includes a substrate, a first transistor and an optical modulating layer. The first transistor is disposed on the substrate and includes a first semiconductor layer having a first channel region, a first gate disposed on the first semiconductor layer, a first source and a first drain electrically connected to the first semiconductor layer respectively and a first interval located between the first source and the first drain, a first insulating layer disposed between the first semiconductor layer and the first gate, and a second insulating layer overlapping the first source, the first drain and the first channel region. The first channel region is corresponding to the first interval. The optical modulating layer is disposed on the second insulating layer and overlaps at least a portion of the first channel region. The value for optical density (OD) of the optical modulating layer is greater than or equal to 0.1 and less than or equal to 6.

Another exemplary embodiment of a display device is provided. The display device includes an image display element and an array substrate. The array substrate includes a substrate, a first transistor and an optical modulating layer. The first transistor is disposed on the substrate and includes a first semiconductor layer having a first channel region, a first gate disposed on and corresponding to the first semiconductor layer, a first source and a first drain electrically connected to the first semiconductor layer respectively and a first interval located between the first source and the first drain, a first insulating layer disposed between the first semiconductor layer and the first gate, and a second insulating layer overlapping the first source, the first drain and the first channel region. The first channel region is corresponding to the first interval. The optical modulating layer is disposed on the second insulating layer and overlaps at least a portion of the first channel region. The value for optical density (OD) of the optical modulating layer is greater than or equal to 0.1 and less than or equal to 6. The display element is disposed on the array substrate.

### BRIEF DESCRIPTION OF THE DRAWINGS

The present disclosure can be further understood by reading the subsequent detailed description and examples with references made to the accompanying drawings, wherein:

FIG. 1 is a cross section of a back channel etch (BCE) type array substrate according to some embodiments of the present disclosure.

FIG. 1-1 is a cross section of an etch stop (ES) type array substrate according to some embodiments of the present disclosure.

FIG. 2 is a cross section of a BCE type array substrate according to some embodiments of the present disclosure.

FIG. 2-1 is a cross section of an ES type array substrate according to some embodiments of the present disclosure.

FIG. 3 is a cross section of a BCE type array substrate according to some embodiments of the present disclosure.

FIG. 3-1 is a cross section of an ES type array substrate according to some embodiments of the present disclosure.

FIG. 4 is a cross section of a BCE type array substrate according to some embodiments of the present disclosure.

FIG. 4-1 is a cross section of an ES type array substrate according to some embodiments of the present disclosure.

FIG. 5 is a cross section of a pixel structure having a BCE type array substrate according to some embodiments of the present disclosure.

FIG. 5-1 is a cross section of a pixel structure having an ES type array substrate according to some embodiments of the present disclosure.

FIG. 6 is a cross section of a pixel structure having a BCE type array substrate according to some embodiments of the present disclosure.

FIG. 6-1 is a cross section of a pixel structure having an ES type array substrate according to some embodiments of the present disclosure.

FIG. 7 schematically shows a display device according to some embodiments of the present disclosure.

### DETAILED DESCRIPTION

The following description is of the best-contemplated mode of carrying out the invention. This description is provided for the purpose of illustrating the general principles of the invention and should not be taken in a limiting sense. The scope of the invention is best determined by reference to the appended claims. Moreover, the same or similar elements in the drawings and the description are labeled with the same reference numbers.

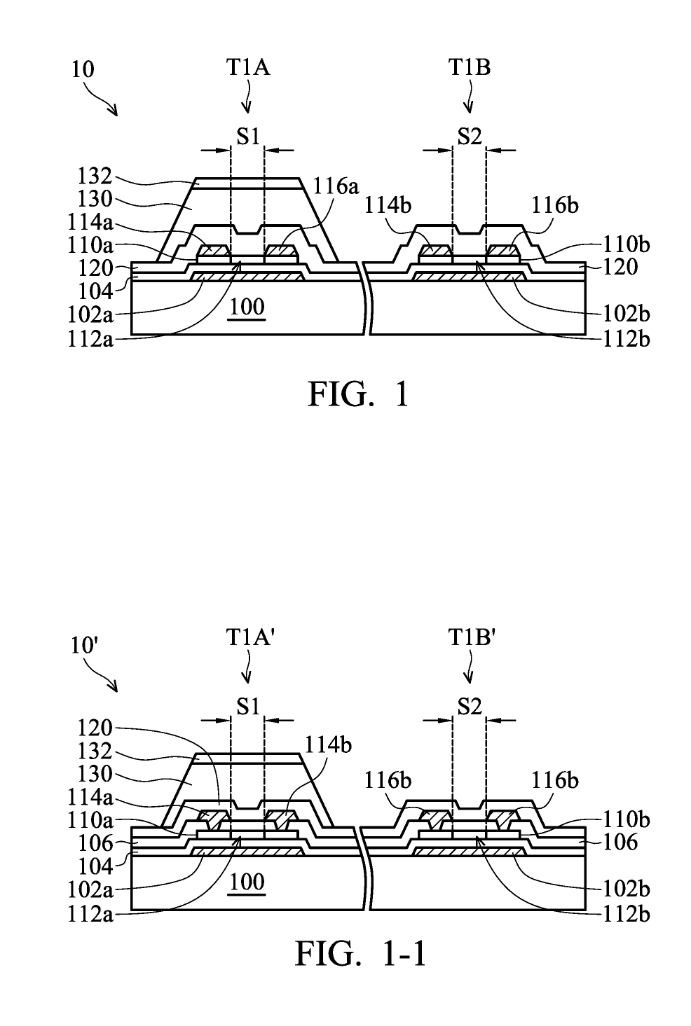

Refer to FIG. 1, in which a cross section of a back channel etch (BCE) type array substrate 10 is shown according to the disclosure. In some embodiments, the array substrate 10 may be implemented in a display device, such as an LCD device, an OLED display device, an LED display device (inorganic) and the like. In some embodiments, the array substrate 10 includes a substrate 100 that is comprised of, for example, glass, quartz, plastic, fiber, rubber, or other transparent materials. In some embodiments, the substrate 10 could comprise metal foil, plastic, fiber, rubber, or other non-transparent materials.

In the embodiment, the array substrate 10 further includes transistors (e.g., thin film transistors) disposed on the substrate 100. Those transistors may include switching elements used in a display region or a peripheral region, driving elements used in the display region or the peripheral region, multiplexers, shift registers, level shifters, buffering circuit, electrostatic discharge (ESD) elements, testing circuit elements, inverters and the like. In order to simplify the diagram and the description, only a first transistor T1A and a second transistor T1B are depicted.

In some embodiments, the first transistor T1A may be a bottom-gate type thin film transistor and include a first gate 102a, a first insulating layer 104 that is disposed on the first gate 102a and the substrate 100, a first semiconductor layer 110a that is disposed on the first insulating layer 104, a first source 114a and a first drain 116a that are disposed on two opposite sides of the first semiconductor layer 110a, and the first source 114a and the first drain 116a are individually electrically connected to the first semiconductor layer 110a, and a second insulating layer 120 that is disposed on the first source 114a, the first drain 116a, the first semiconductor layer 110a, and the first insulating layer 104.

In some embodiments, the first gate 102a is disposed on and corresponds to the first semiconductor layer 110a. Moreover, the first gate 102a may include copper, aluminum, gold, silver, molybdenum, tungsten, titanium, chromium, an alloy thereof, or another suitable electrode material. In some embodiments, the first semiconductor layer 110a may have a first channel region 112a and be made of amorphous silicon, polysilicon (e.g., low temperature polysilicon, LTPS), metal oxide semiconductor (e.g., indium gallium zinc oxide (IGZO), indium zinc oxide (IZO), indium gallium oxide (IGO), indium tin zinc oxide (ITZO), or the like). In some embodiments, the first insulating layer 104 is disposed between the first semiconductor layer 110a and the first gate 102a, so as to serve as a gate insulating layer of the first transistor T1A. Moreover, the first insulating layer 104 may include organic insulating materials, or inorganic materials such as silicon oxide, silicon nitride, or a combination thereof.

In some embodiments, the first source 114a and the first drain 116a are individually electrically connected to the first semiconductor layer 110a. A first interval S1 is located between the first source 114a and the first drain 116a, and the first channel region 112a of the first semiconductor layer 110a is disposed corresponding to the first interval S1. Moreover, the first source 114a and the first drain 116a may include copper, aluminum, gold, silver, molybdenum, tungsten, titanium, chromium, an alloy thereof, or another suitable electrode material. The first source 114a and the first drain 116a may be a single layer or have a multi-layer structure. For example, the first source 114a and the first drain 116a are a multi-layer structure of Mo/Al/Mo (molybdenum/aluminum/molybdenum). In some embodiments, the second insulating layer 120 disposed on the first source 114a and the first drain 116a serves as a passivation layer and covers the first channel region 112a of the first semiconductor layer 110a via the first interval S1 between the first source 114a and the first drain 116a. Moreover, the second insulating layer 120 may include an inorganic insulating material, such as silicon oxide, silicon nitride, or a combination thereof. In other embodiment, the second insulating layer 120 may include an organic insulating material.

In some embodiments, the second transistor T1B may be a bottom-gate type thin film transistor and have a structure that is similar to that of the first transistor T1A. For example, the second transistor T1B includes a second gate 102b, the first insulating layer 104 that is disposed on the second gate 102b and the substrate 100, a second semiconductor layer 110b that is disposed on the first insulating layer 104, a second source 114b and a second drain 116b that are disposed on the second semiconductor layer 110b, and the second insulating layer 120 that is disposed on the second source 114b, the second drain 116b, the first insulating layer 104, and the second insulating layer 120.

Similarly, the second gate 102b is disposed on and corresponding to the second semiconductor layer 110b, so that the second gate 102b partially overlaps the second semiconductor layer 110b. Moreover, the second gate 102b may include a material which is the same as or similar to that of the first gate 102a. The second semiconductor layer 110b has a second channel region 112b and may include a material which is the same as or similar to that of the first semiconductor layer 110a. The first insulating layer 104 is disposed between the second semiconductor layer 110b and the second gate 102b, so as to serve as a gate insulating layer of the second transistor T1B. The second source 114b and the second drain 116b are disposed two opposite sides of the second semiconductor layer 110b and individually electrically connected to the second semiconductor layer 110b. A second interval S2 is located between the second source 114b and the second drain 116b and the second channel region 112b of the second semiconductor layer 110b is disposed corresponding to the second interval S2. Moreover, the second source 114b and the second drain 116b may include a material which is the same as or similar to that of the first source 114a and the first drain 116a. The second insulating layer 120 (passivation layer) disposed on the second source 114b and the second drain 116b covers the second channel region 112b of the second semiconductor layer 110b via the second interval S2 between the second source 114b and the second drain 116b.

In the embodiment, the array substrate 10 further includes an optical modulating layer 130. In some embodiments, the optical modulating layer 130 is disposed on the second insulating layer 120. Moreover, when viewed from a top-view perspective (along the normal direction of the substrate 10), the optical modulating layer 130 overlaps at least a portion of the first channel region 112a of the first transistor T1A and does not overlap the second channel region 112b of the second transistor T1B. In some examples, the optical modulating layer 130 may entirely overlap the first channel region 112a of the first transistor T1A, as shown in FIG. 1. In those cases, the optical modulating layer 130 may overlaps at least a portion of the first gate 102a of the first transistor T1A and the top surfaces and sidewalls of the first source 114a and the first drain 116a of the first transistor T1A further. In some other examples, the optical modulating layer 130 may overlap a half of the first channel region 112a of the first transistor T1A. The optical modulating layer 130 provides protection for the first channel region 112a of the first transistor T1A, thereby mitigating the impact of the light irradiation on the first transistor T1A.

In some embodiments, the optical modulating layer 130 may be a single layer or a multi-layer structure and include a colored photoresist or resin or another suitable light-shielding material. In accordance with some embodiments, the optical modulating layer 130 is made of a black photoresist. In accordance with some embodiments, the optical modulating layer 130 is made of a colored photoresist, such as a red photoresist, a green photoresist, a blue photoresist, a grey photoresist, or a combination thereof. In accordance with some embodiments, the optical modulating layer 130 has an optical density (OD), in which the OD value of the optical modulating layer 130 is greater than or equal to 0.1 and less than or equal to 6. For example, the OD value is greater than or equal to 3 and less than or equal to 6. Alternatively, the OD value is greater than or equal to 4 and less than or equal to 5. In the embodiment, the definition of the optical density (OD) is as follows:

OD=−log(I/Io)

Where Io is original light intensity and I is the light intensity of the light after passing through the optical modulating layer.

In some embodiments, the optical modulating layer 130 may be replaced with an opaque material layer (e.g., a metal layer), so as to protect the first channel region 112a of the first semiconductor layer 110a.

In the embodiment, the array substrate 10 may include a display region and a peripheral region, in which the peripheral region is located outside of the display region. It should be understood that the optical modulating layer 130 may selectively overlap the first transistor T1A and/or the second transistor T1B according to the design demands of the circuit.

In some examples, the first transistors T1A and the second transistors T1B are disposed in the peripheral region of the array substrate 10. In those cases, the optical modulating layer 130 overlaps the first transistor T1A in the peripheral region and does not overlap the second transistor T1B. Namely, the optical modulating layer 130 may be formed on some transistors (not shown) in the peripheral region according to the design demands of the circuit. However, it should be understood that the optical modulating layer 130 may overlap all of the transistors in the peripheral region.

In some examples, the first transistors T1A and the second transistors T1B are disposed in the display region of the array substrate 10. In those cases, the optical modulating layer 130 overlaps the first transistor T1A in the display region and does not overlap the second transistor T1B. Namely, the optical modulating layer 130 may be formed on some transistors (not shown) in the display region according to the design demands of the circuit. However, it should be understood that the optical modulating layer 130 may overlap all of the transistors in the display region.

In some examples, the first transistors T1A and the second transistors T1B are respectively disposed in the display region and the peripheral region of the array substrate 10. In those cases, the optical modulating layer 130 overlaps the first transistor T1A in the display region and does not overlap the second transistor T1B in the peripheral region. Namely, the optical modulating layer 130 may be formed on at least one of the transistors (e.g., the first transistors T1A) in the display region according to the design demands of the circuit. Moreover, the optical modulating layer 130 may not be formed on at least one of the transistors (e.g., the second transistors T1B) in the peripheral region according to the design demands of the circuit.

In some examples, the first transistors T1A and the second transistors T1B are respectively disposed in the peripheral region and the display region of the array substrate 10. In those cases, the optical modulating layer 130 overlaps the first transistor T1A in the peripheral region and does not overlap the second transistor T1B in the display region. Namely, the optical modulating layer 130 may be formed on at least one of the transistors (e.g., the first transistors T1A) in the peripheral region according to the design demands of the circuit. Moreover, the optical modulating layer 130 may not be formed on at least one of the transistors (e.g., the second transistors T1B) in the display region according to the design demands of the circuit.

In the embodiment, the array substrate 10 further includes a conductive layer 132. The conductive layer 132 is disposed on the optical modulating layer 130, so that the optical modulating layer 130 is interposed between the conductive layer 132 and the second insulating layer 120. The conductive layer 132 may serve as a first electrode layer and be electrically connected to the first source 114a or the first drain 116a. In some embodiments, the conductive layer 132 (the first electrode layer) may include a transparent material (such as indium tin oxide (ITO) or indium zinc oxide (IZO)) or metal (such as copper, aluminum, gold, silver, molybdenum, tungsten, titanium, chromium, an alloy thereof, or another suitable metal electrode material).

Refer to FIG. 1-1, in which a cross section of an etch stop (ES) type array substrate 10′ is shown according to the disclosure. Elements in FIG. 1-1 that are the same as those in FIG. 1 are labeled with the same reference numbers as in FIG. 1 and are not described again for brevity. In the embodiment, the structure of the array substrate 10′ is similar to that of the array substrate 10 shown in FIG. 1, and therefore it has the same advantages as those of the array substrate 10. Unlike the structure of the array substrate 10, the array substrate 10′ further includes an etch stop layer 106. The etch stop layer 106 is disposed in the first transistor T1A′ and between the first semiconductor layer 110a and the first source 114a and first drain 116a. Moreover, the etch stop layer 106 is also disposed in the second transistor T1B′ and between the second semiconductor layer 110b and the second source 114b and second drain 116b. The etch stop layer 106 has openings, so that the first source 114a and the first drain 116a are electrically connected to the first semiconductor layer 110a via the openings and the second source 114b and second drain 116b are electrically connected to the second semiconductor layer 110b via the openings.

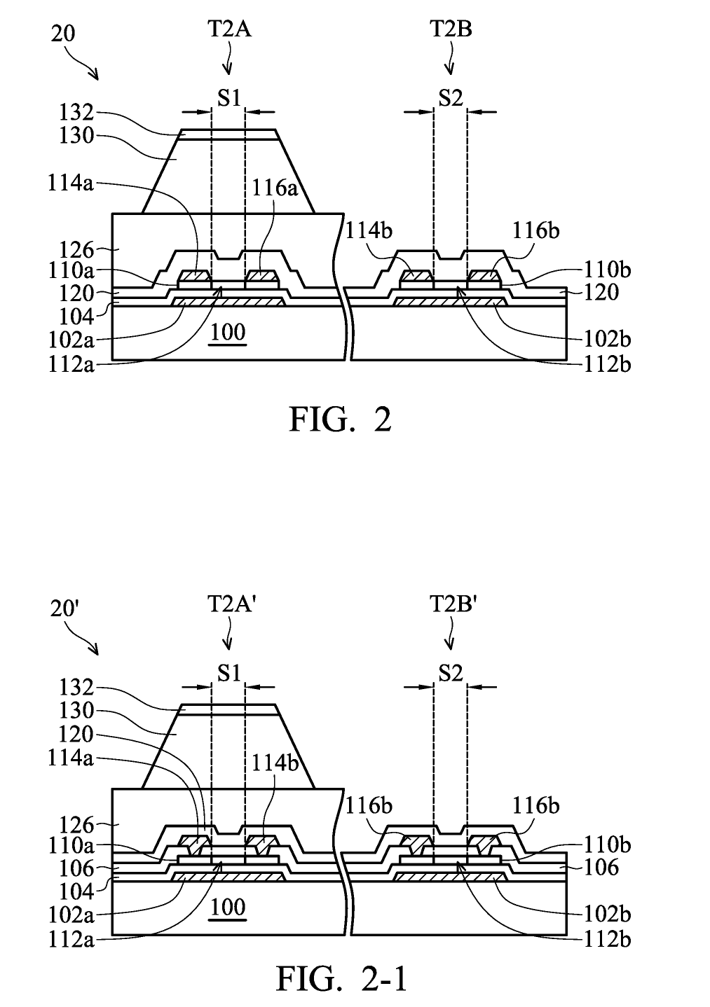

Refer to FIG. 2, in which a cross section of a back channel etch (BCE) type array substrate 20 is shown according to the disclosure. Elements in FIG. 2 that are the same as those in FIG. 1 are labeled with the same reference numbers as in FIG. 1 and are not described again for brevity. In the embodiment, the structure of the array substrate 20 is similar to that of the array substrate 10 shown in FIG. 1, and therefore it has the same advantages as those of the array substrate 10. Unlike the structure of the array substrate 10, the array substrate 20 further includes a third insulating layer 126 that is disposed on the first transistor T2A and is not disposed on the second transistor T2B. In some embodiments, the third insulating layer 126 is disposed between the conductive layer 132 (first electrode layer) and the second insulating layer 120. In some other embodiments, the conductive layer 132 may be disposed between the optical modulating layer 130 and the third insulating layer 126.

In the embodiment, the third insulating layer 126 may serve as a planarization layer and be interposed between the optical modulating layer 130 and the second insulating layer 120, as shown in FIG. 2. The third insulating layer 126 may include an organic material or an inorganic material. The organic material may include poly fluoro alkoxy (PFA), polyimide, siloxane-based resin, phosphosilicate (PSG), borophosphosilicate glass (BPSG).

Refer to FIG. 2-1, in which a cross section of an etch stop (ES) type array substrate 20′ is shown according to the disclosure. Elements in FIG. 2-1 that are the same as those in FIG. 2 are labeled with the same reference numbers as in FIG. 2 and are not described again for brevity. In the embodiment, the structure of the array substrate 20′ is similar to that of the array substrate 20 shown in FIG. 2, and therefore it has the same advantages as those of the array substrate 20. Unlike the structure of the array substrate 20, the array substrate 20′ further includes an etch stop layer 106. The etch stop layer 106 is disposed in the first transistor T2A′ and between the first semiconductor layer 110a and the first source 114a and first drain 116a. Moreover, the etch stop layer 106 is also disposed in the second transistor T2B′ and between the second semiconductor layer 110b and the second source 114b and second drain 116b. The etch stop layer 106 has openings, so that the first source 114a and the first drain 116a are electrically connected to the first semiconductor layer 110a via the openings and the second source 114b and second drain 116b are electrically connected to the second semiconductor layer 110b via the openings.

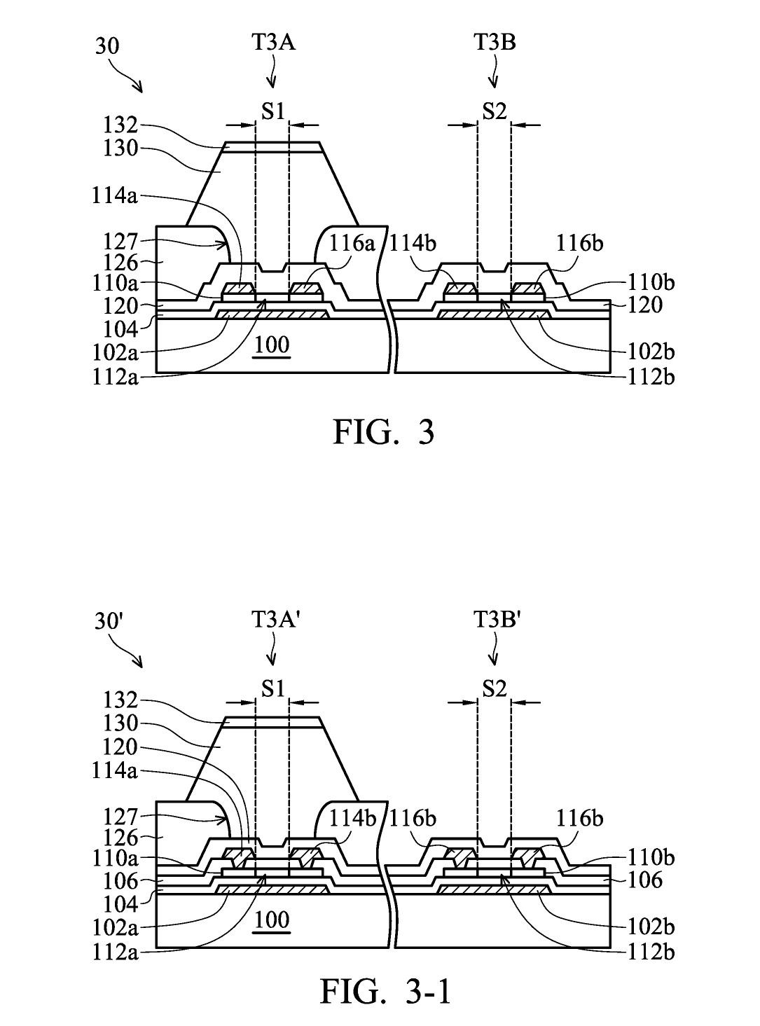

Refer to FIG. 3, in which a cross section of a back channel etch (BCE) type array substrate 30 is shown according to the disclosure. Elements in FIG. 3 that are the same as those in FIG. 2 are labeled with the same reference numbers as in FIG. 2 and are not described again for brevity. In the embodiment, the structure of the array substrate 30 is similar to that of the array substrate 20 shown in FIG. 2, and therefore it has the same advantages as those of the array substrate 20. In the embodiment, the third insulating layer 126 is disposed on the first transistor T3A and is not disposed on the second transistor T3B. Moreover, unlike the structure of the array substrate 20, the third insulating layer 126 has an opening 127 corresponding to the first channel region 112a of the first semiconductor layer 110a of the first transistor T3A and exposing the underlying second insulating layer 120. Moreover, the optical modulating layer 130 fills the opening 127, so that the optical modulating layer 130 has a T-shaped profile structure. In some embodiments, the conductive layer 132 is disposed on the optical modulating layer 130, as shown in FIG. 3. In some other embodiments, the conductive layer 132 may be disposed on the third insulating layer 126 and outside of the optical modulating layer 130.

Refer to FIG. 3-1, in which a cross section of an etch stop (ES) type array substrate 30′ is shown according to the disclosure. Elements in FIG. 3-1 that are the same as those in FIG. 3 are labeled with the same reference numbers as in FIG. 3 and are not described again for brevity. In the embodiment, the structure of the array substrate 30′ is similar to that of the array substrate 30 shown in FIG. 3, and therefore it has the same advantages as those of the array substrate 30. Unlike the structure of the array substrate 30, the array substrate 30′ further includes an etch stop layer 106. The etch stop layer 106 is disposed in the first transistor T3A′ and between the first semiconductor layer 110a and the first source 114a and first drain 116a. Moreover, the etch stop layer 106 is also disposed in the second transistor T3B′ and between the second semiconductor layer 110b and the second source 114b and second drain 116b. The etch stop layer 106 has openings, so that the first source 114a and the first drain 116a are electrically connected to the first semiconductor layer 110a via the openings and the second source 114b and second drain 116b are electrically connected to the second semiconductor layer 110b via the openings.

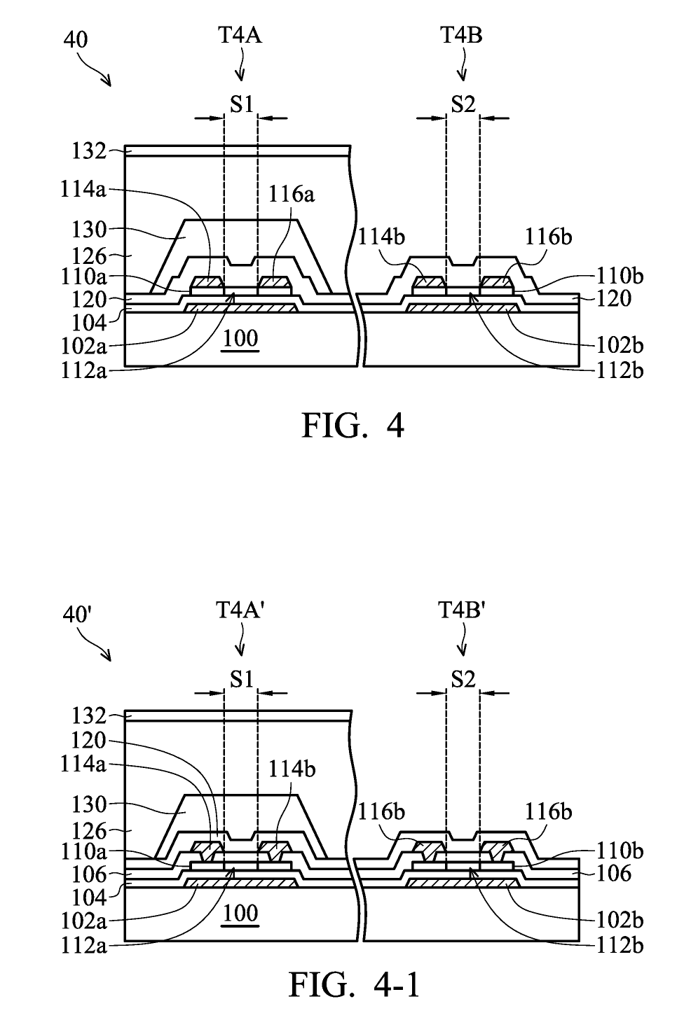

Refer to FIG. 4, in which a cross section of a back channel etch (BCE) type array substrate 40 is shown according to the disclosure. Elements in FIG. 4 that are the same as those in FIG. 1 are labeled with the same reference numbers as in FIG. 1 and are not described again for brevity. In the embodiment, the structure of the array substrate 40 is similar to that of the array substrate 10 shown in FIG. 1, and therefore it has the same advantages as those of the array substrate 10. Unlike the structure of the array substrate 10, the array substrate 40 further includes the third insulating layer 126 that is disposed on the first transistor T4A and is not disposed on the second transistor T4B. Moreover, the third insulating layer 126 is disposed between the conductive layer 132 (first electrode layer) and the optical modulating layer 130. For example, the conductive layer 132 may be disposed on the third insulating layer 126 that serves as a planarization layer. Moreover, the third insulating layer 126 overlaps the top surface and sidewalls of the optical modulating layer 130, as shown in FIG. 4.

Refer to FIG. 4-1, in which a cross section of an etch stop (ES) type array substrate 40′ is shown according to the disclosure. Elements in FIG. 4-1 that are the same as those in FIG. 4 are labeled with the same reference numbers as in FIG. 4 and are not described again for brevity. In the embodiment, the structure of the array substrate 40′ is similar to that of the array substrate 40 shown in FIG. 4, and therefore it has the same advantages as those of the array substrate 40. Unlike the structure of the array substrate 40, the array substrate 40′ further includes an etch stop layer 106. The etch stop layer 106 is disposed in the first transistor T4A′ and between the first semiconductor layer 110a and the first source 114a and first drain 116a. Moreover, the etch stop layer 106 is also disposed in the second transistor T4B′ and between the second semiconductor layer 110b and the second source 114b and second drain 116b. The etch stop layer 106 has openings, so that the first source 114a and the first drain 116a are electrically connected to the first semiconductor layer 110a via the openings and the second source 114b and second drain 116b are electrically connected to the second semiconductor layer 110b via the openings.

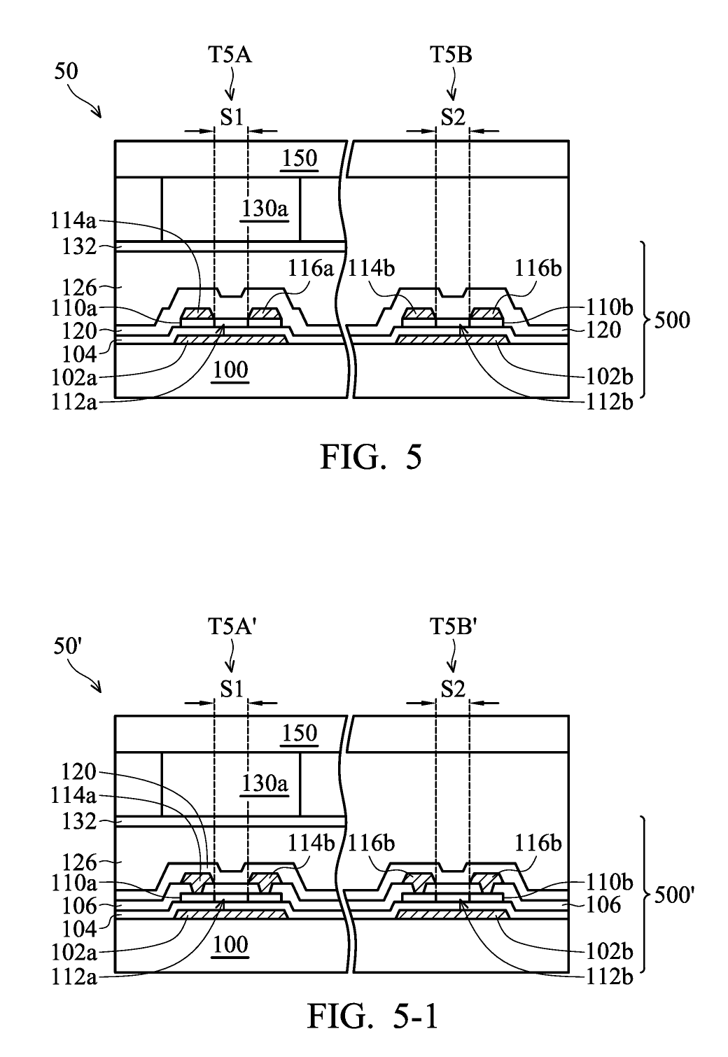

Refer to FIG. 5, in which a pixel structure 50 has a back channel etch (BCE) type array substrate according to some embodiments of the present disclosure. Elements in FIG. 5 that are the same as those in FIG. 2 are labeled with the same reference numbers as in FIG. 2 and are not described again for brevity. In the embodiment, the pixel structure 50 may be implemented in a liquid-crystal display device. Moreover, the pixel structure 50 may include an array substrate 500, an opposing substrate 150 disposed opposite to the array substrate 500, and an optical modulating layer 130a disposed between the array substrate 500 and the opposing substrate 150. The opposing substrate 150 may include a color filter layer (not shown), so as to serve as a color filter substrate. Alternatively, the color filter layer (not shown) may be disposed on the array substrate 500, so as to form a color filter on array (COA) structure. In other embodiment, the pixel structure 50 may be implemented in an inorganic light emitting diode display device (micrometer size LED, micro-LED) or an organic light emitting diode display device (OLED), the optical modulating layer 130a could be replaced as a plurality of inorganic light emitting diodes or a plurality of light emitting diodes, and color filter layer is disposed optionally.

In the embodiment, the structure of the array substrate 500 of the pixel structure 500 is similar to that of the array substrate 20 shown in FIG. 2, and therefore it has the same advantages as those of the array substrate 20. However, the difference between FIG. 5 and FIG. 2 is the location relationship between the conductive layer (first electrode layer) and the optical modulating layer. In FIG. 2, the optical modulating layer 130 is disposed between the conductive layer 132 (first electrode layer) and the second insulting layer 120. In FIG. 5, however, the conductive layer 132 (first electrode layer) is disposed between the optical modulating layer 130a and the second insulting layer 120. Moreover, the optical modulating layer 130a in the pixel structure 50 has a thickness that is greater than that of the optical modulating layer 130 in the array substrate 20. For example, the thickness of the optical modulating layer 130a is substantially equal to that of a spacer used in a pixel structure of a liquid-crystal display device. Therefore, the optical modulating layer 130a may be used as a spacer located between the array substrate 500 and the opposing substrate 150. The spacer may support a space between the array substrate 500 and the opposing substrate 150. Namely, it may support a cell gap between the array substrate 500 and the opposing substrate 150. The arrangement of the optical modulating layer 130a is similar to that of the optical modulating layer 130 in the array substrate 20 and is disposed on the third insulating layer 126. Moreover, when viewed from a top-view perspective, the optical modulating layer 130a overlaps at least a portion of the first channel region 112a of the first transistor T5A and does not overlap the second channel region 112b of the second transistor T5B. In some examples, the optical modulating layer 130a may entirely overlap the first channel region 112a of the first transistor T5A, as shown in FIG. 5.

The optical modulating layer 130a is not only capable of maintaining the cell gap, but also providing protection for the first channel region 112a of the first semiconductor layer 110a, so as to mitigate the impact of the light irradiation on the first transistor T5A.

In some embodiments, the conductive layer 132 is disposed between the third insulating layer 126 and the optical modulating layer 130a. In some embodiments, the opposing substrate 150 may include a black matrix (not shown). In accordance with some embodiments, the array substrate 500 may include a black matrix (not shown) and the optical modulating layer 130a is made of a material which is the same as that of the black matrix. In accordance with some embodiments, the optical modulating layer 130a and the black matrix are made of the same layer and formed by the same process.

Refer to FIG. 5-1, in which a cross section of a pixel structure 50′ having an etch stop (ES) type array substrate is shown according to the disclosure. Elements in FIG. 5-1 that are the same as those in FIG. 5 are labeled with the same reference numbers as in FIG. 5 and are not described again for brevity. In the embodiment, the structure of the pixel structure 50′ is similar to that of the pixel structure 50 shown in FIG. 5, and therefore it has the same advantages as those of the array substrate 50. Unlike the structure of the pixel structure 50, the array substrate 500′ of the pixel structure 50′ further includes an etch stop layer 106. The etch stop layer 106 is disposed in the first transistor T5A′ and between the first semiconductor layer 110a and the first source 114a and first drain 116a. Moreover, the etch stop layer 106 is also disposed in the second transistor T5B′ and between the second semiconductor layer 110b and the second source 114b and second drain 116b. The etch stop layer 106 has openings, so that the first source 114a and the first drain 116a are electrically connected to the first semiconductor layer 110a via the openings and the second source 114b and second drain 116b are electrically connected to the second semiconductor layer 110b via the openings.

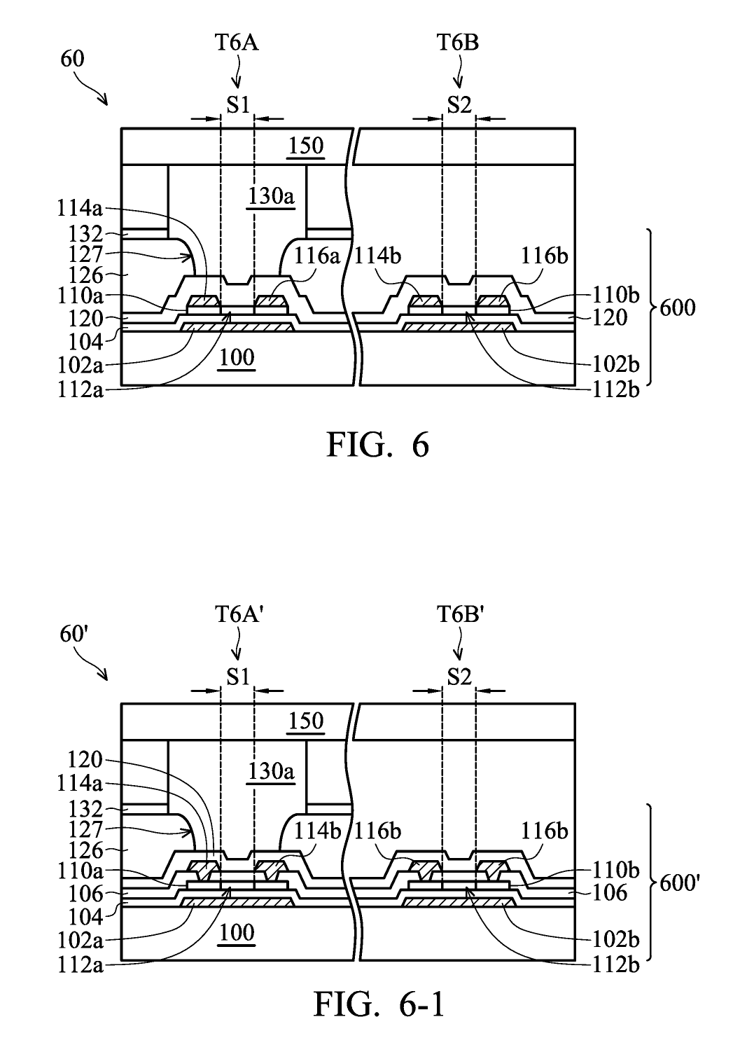

Refer to FIG. 6, in which a pixel structure 60 has a back channel etch (BCE) type array substrate according to some embodiments of the present disclosure. Elements in FIG. 6 that are the same as those in FIG. 5 are labeled with the same reference numbers as in FIG. 5 and are not described again for brevity. In the embodiment, the structure of the pixel structure 60 is similar to that of the pixel structure 50 shown in FIG. 5, and therefore it has the same advantages as those of the pixel structure 50. In the embodiment, the third insulating layer 126 is disposed on the first transistor T6A and is not disposed on the second transistor T6B. Moreover, unlike the structure of the pixel structure 50, the third insulating layer 126 has an opening 127 corresponding to the first channel region 112a of the first semiconductor layer 110a of the first transistor T6A and exposing the underlying second insulating layer 120. Moreover, the optical modulating layer 130a fills the opening 127, so that the optical modulating layer 130a has a T-shaped profile structure. In some embodiments, the conductive layer 132 may be disposed on the third insulating layer 126 and outside of the optical modulating layer 130a. Similar to FIG. 5, the optical modulating layer 130a may serve as a spacer disposed between the array substrate 600 and the opposing substrate 150. The spacer is capable of supporting and maintaining the cell gap between the array substrate 600 and the opposing substrate 150.

Refer to FIG. 6-1, in which a cross section of a pixel structure 60′ having an etch stop (ES) type array substrate is shown according to the disclosure. Elements in FIG. 6-1 that are the same as those in FIG. 6 are labeled with the same reference numbers as in FIG. 6 and are not described again for brevity. In the embodiment, the structure of the pixel structure 60′ is similar to that of the pixel structure 60 shown in FIG. 6, and therefore it has the same advantages as those of the array substrate 60. Unlike the structure of the pixel structure 60, the array substrate 600′ of the pixel structure 60′ further includes an etch stop layer 106. The etch stop layer 106 is disposed in the first transistor T6A′ and between the first semiconductor layer 110a and the first source 114a and first drain 116a. Moreover, the etch stop layer 106 is also disposed in the second transistor T6B′ and between the second semiconductor layer 110b and the second source 114b and second drain 116b. The etch stop layer 106 has openings, so that the first source 114a and the first drain 116a are electrically connected to the first semiconductor layer 110a via the openings and the second source 114b and second drain 116b are electrically connected to the second semiconductor layer 110b via the openings.

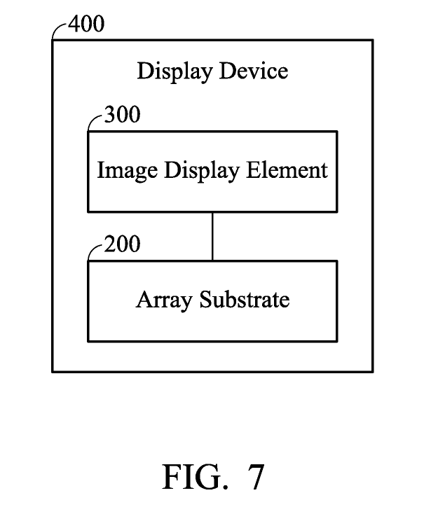

Refer to FIG. 7, in which a display device 400 is schematically shown according to some embodiments of the present disclosure. In some embodiments, the display device 400 may include an array substrate 200 and an image display element 300. The image display element 300 may be an LCD element (sub-pixels), an OLED display element, or a micro-LED display element and be electrically connected to the array substrate 200. As a result, the formed display device 400 may be an LCD device, an OLED display device or a micro-LED display device. In the embodiment, the array substrate 200 may be the same as one of the array substrates 10, 20, 30, and 40 respectively shown in FIGS. 1 to 4 or one of the array substrates 10′, 20′, 30′, and 40′ respectively shown in FIGS. 1-1 to 4-1. In some other embodiments, the display device 400 may be an LCD device and the pixel structure of the display device 400 may be the same as one of the pixel structures 50 and 60 respectively shown in FIGS. 5 and 6 or one of the pixel structures 50′ and 60′ respectively shown in FIGS. 5-1 and 6-1.

According to the foregoing embodiments, an optical modulating layer is disposed over the channel region of the thin film transistor on the array substrate, thereby preventing or mitigating the impact of the light irradiation on the properties of the thin film transistor. According to the foregoing embodiments, the quality of the display device can be increased.

Moreover, according to the foregoing embodiments, the thickness of the optical modulating layer is increased to serve as a spacer in the pixel structure. As a result, it is not necessary to additionally form the spacers in the pixel structure or the number of spacers can be reduced.

While the disclosure has been described by way of example and in terms of the preferred embodiments, it should be understood that the disclosure is not limited to the disclosed embodiments. On the contrary, it is intended to overlap various modifications and similar arrangements (as would be apparent to those skilled in the art). Therefore, the scope of the appended claims should be accorded the broadest interpretation so as to encompass all such modifications and similar arrangements.

What is claimed is:

1. An array substrate, comprising:
a substrate;
a first transistor disposed on the substrate and comprising:
a first semiconductor layer having a first channel region;
a first gate disposed on the first semiconductor layer;
a first source and a first drain electrically connected to the first semiconductor layer respectively, wherein a first interval is located between the first source and the first drain, and the first channel region is corresponding to the first interval;
a first insulating layer disposed between the first semiconductor layer and the first gate; and
a second insulating layer overlapping the first source, the first drain and the first channel region; and
an optical modulating layer disposed on the second insulating layer,
wherein the optical modulating layer overlaps at least a portion the first channel region, and a value of an optical density (OD) of the optical modulating layer is greater than or equal to 0.1 and less than or equal to 6.

2. The array substrate as claimed in claim 1, further comprising:
a second transistor disposed on the substrate, wherein the second transistor comprises:
a second semiconductor layer having a second channel region;
a second gate overlapping at least a portion of the second semiconductor layer;
a second source and a second drain electrically connected to the second semiconductor layer respectively, wherein a second interval is located between the second source and the second drain and the second channel region is corresponding to the second interval;
the first insulating layer disposed between the second semiconductor layer and the second gate; and
the second insulating layer overlapping the second source, the second drain and the second channel region,
wherein the optical modulating layer does not overlap the second channel region.

3. The array substrate as claimed in claim 2, wherein the first semiconductor layer comprises a material comprising metal oxide semiconductor, polysilicon, or amorphous silicon and the second semiconductor layer comprises a material comprising metal oxide semiconductor, polysilicon, or amorphous silicon.

4. The array substrate as claimed in claim 2, wherein the substrate comprises a display region and a peripheral region outside of the display region, and wherein both the first transistor and the second transistor are disposed in the peripheral region.

5. The array substrate as claimed in claim 2, wherein the substrate comprises a display region and a peripheral region outside of the display region, and wherein both the first transistor and the second transistor are disposed in the display region.

6. The array substrate as claimed in claim 2, wherein the substrate comprises a display region and a peripheral region outside of the display region, and wherein the first transistor is disposed in the peripheral region and the second transistor is disposed in the display region.

7. The array substrate as claimed in claim 2, wherein the substrate comprises a display region and a peripheral region outside of the display region, and wherein the first transistor is disposed in the display region and the second transistor is disposed in the peripheral region.

8. The array substrate as claimed in claim 1, further comprising a first electrode layer electrically connected to the first source or the first drain.

9. The array substrate as claimed in claim 8, wherein the optical modulating layer is disposed between the first electrode layer and the second insulating layer.

10. The array substrate as claimed in claim 8, further comprising a third insulating layer disposed between the first electrode layer and the second insulating layer.

11. A display device, comprising:
an array substrate comprising:
a substrate;
a first transistor disposed on the substrate and comprising:
a first semiconductor layer having a first channel region;
a first gate disposed on the first semiconductor layer;
a first source and a first drain electrically connected to the first semiconductor layer respectively, wherein a first interval is located between the first source and the first drain and the first channel region is corresponding to the first interval;
a first insulating layer disposed between the first semiconductor layer and the first gate; and
a second insulating layer overlapping the first source, the first drain and the first channel region; and
an optical modulating layer disposed on the second insulating layer,
wherein the optical modulating layer overlaps at least a portion of the first channel region, and a value of an optical density (OD) of the optical modulating layer is greater than or equal to 0.1 and less than or equal to 6; and
a display element disposed on the array substrate.

12. The display device as claimed in claim 11, wherein the array substrate further comprises:
a second transistor disposed on the substrate, wherein the second transistor comprises:
a second semiconductor layer having a second channel region;
a second gate overlapping at least a portion of the second semiconductor layer;
a second source and a second drain electrically connected to the second semiconductor layer respectively, wherein a second interval is located between the second source and the second drain and the second channel region is corresponding to the second interval;
the first insulating layer disposed between the second semiconductor layer and the second gate; and
the second insulating layer overlapping the second source, the second drain and the second channel region,
wherein the optical modulating layer does not overlap the second channel region.

13. The display device as claimed in claim 11, wherein the array substrate further comprises a first electrode layer electrically connected to the first source or the first drain.

14. The display device as claimed in claim 13, wherein the optical modulating layer of the array substrate is disposed between the first electrode layer and the second insulating layer.

15. The display device as claimed in claim 13, wherein the first electrode layer of the array substrate is disposed between the optical modulating layer and the second insulating layer.

16. The display device as claimed in claim 13, wherein the array substrate further comprises a third insulating layer disposed between the first electrode layer and the second insulating layer.

17. The display device as claimed in claim 16, wherein the third insulating layer has an opening and the optical modulating layer fills the opening.

18. The display device as claimed in claim 11, wherein the value of the OD of the optical modulating layer is greater than or equal to 4 and less than or equal to 5.

19. The display device as claimed in claim 11, further comprising an opposing substrate, wherein the optical modulating layer is a spacer to support a space between the substrate and the opposing substrate.

20. The display device as claimed in claim 11, wherein the display element comprises a liquid-crystal display element, an organic light-emitting diode display element, or a micro-light-emitting diode display element.
